(19) United States
(12) Patent Application Publication
(10) Pub. No.: US 2024/0359286 A1
(43) Pub. Date: Oct. 31, 2024

(54) CHEMICAL MECHANICAL POLISHING APPARATUS AND A METHOD OF POLISHING A SUBSTRATE USING THE SAME

(71) Applicant: SAMSUNG ELECTRONICS CO., LTD., Suwon-si (KR)

(72) Inventors: Donghoon KWON, Suwon-si (KR); Byoungho Kwon, Suwon-si (KR); Boun Yoon, Suwon-si (KR)

(73) Assignee: SAMSUNG ELECTRONICS CO., LTD., Suwon-si (KR)

(21) Appl. No.: 18/384,680

(22) Filed: Oct. 27, 2023

(30) Foreign Application Priority Data
Apr. 28, 2023 (KR) 10-2023-0056221

(51) Int. Cl. B24B 37/04; B24B 37/10; B24B 37/32

(52) U.S. Cl. CPC B24B 37/042; B24B 37/107; B24B 37/32

(57) ABSTRACT

A chemical mechanical polishing apparatus includes a first polishing pad for polishing a substrate, a first polishing head on the first polishing pad to support a substrate, and a second polishing pad spaced apart from the first polishing pad in a horizontal direction. A radius of the second polishing pad is less than a radius of the first polishing pad.

### CROSS-REFERENCE TO RELATED APPLICATIONS

This application is based on and claims priority under 35 U.S.C. § 119 to Korean Patent Application No. 10-2023-0056221, filed on Apr. 28, 2023, in the Korean Intellectual Property Office, the entire contents of which are hereby incorporated by reference.

### BACKGROUND

### 1. Field

The disclosure relates to a chemical mechanical polishing apparatus and a method of polishing a substrate using the same, and more particularly, to a chemical mechanical polishing apparatus including an auxiliary polishing pad capable of performing an auxiliary polishing process before and/or after a main polishing process and a method of polishing a substrate using the same.

### 2. Description of Related Art

A semiconductor device may be manufactured through various processes. For example, the semiconductor device may be manufactured through a photolithography process, an etching process, a deposition process, etc. may be performed on a substrate to manufacture a semiconductor device. Before each of the processes, it may be required to planarize a surface of the substrate. To achieve this, a polishing process may be performed on the substrate. The polishing process may be performed by at least one of various methods. For example, a chemical mechanical polishing (CMP) process may be used to planarize the substrate.

### SUMMARY

According to an aspect of the disclosure, there is provided a chemical mechanical polishing apparatus capable of performing an auxiliary polishing process as well as a main polishing process in a single chemical mechanical polishing apparatus, and a method of polishing a substrate using the same.

According to another aspect of the disclosure, there is provided a chemical mechanical polishing apparatus capable of performing an auxiliary polishing process on a local portion of a substrate, and a method of polishing a substrate using the same.

According to another aspect of the disclosure, there is provided a chemical mechanical polishing apparatus capable of performing a main or auxiliary polishing process while moving a plurality of polishing heads together, and a method of polishing a substrate using the same.

According to another aspect of the disclosure, there is provided a chemical mechanical polishing apparatus including a carrier capable of transferring a substrate from the outside into the chemical mechanical polishing apparatus, and a method of polishing a substrate using the same.

According to an aspect of the disclosure, there is provided a chemical mechanical polishing apparatus including: a first polishing pad configured to polish a substrate; a first polishing head on the first polishing pad and configured to support the substrate; and a second polishing pad spaced apart from the first polishing pad in a first direction, wherein a radius of the second polishing pad is less than a radius of the first polishing pad.

According to another aspect of the disclosure, there is provided a chemical mechanical polishing apparatus including: a first polishing pad configured to polish a substrate; a first polishing head provided on the first polishing pad; a second polishing pad spaced apart from the first polishing pad: a second polishing head provided on the second polishing pad; a polishing head transferring member connected to the first polishing head and the second polishing head; and a carrier configured to transfer the substrate onto the first polishing head or the second polishing head.

According to another aspect of the disclosure, there is provided a method of polishing a substrate in a chemical mechanical polishing apparatus including a first polishing pad and a second polishing pad, the method including: performing a first polishing process on a substrate on the second polishing pad; moving the substrate to the first polishing pad; and performing a second polishing process on the substrate on the first polishing pad.

### BRIEF DESCRIPTION OF DRAWINGS

FIG. 1 is a perspective view illustrating a chemical mechanical polishing apparatus according to an embodiment.

FIG. 2 is a plan view illustrating a chemical mechanical polishing apparatus according to an embodiment.

FIG. 3 is a front view illustrating a chemical mechanical polishing apparatus according to an embodiment.

FIG. 4 is a perspective view illustrating a chemical mechanical polishing apparatus according to an embodiment.

FIG. 5 is a plan view illustrating a chemical mechanical polishing apparatus according to an embodiment.

FIG. 6 is a front view illustrating a chemical mechanical polishing apparatus according to an embodiment.

FIG. 7 is a front view illustrating an auxiliary polishing part according to an embodiment.

FIG. 8 is a front view illustrating an auxiliary polishing part according to an embodiment.

FIG. 9 is a perspective view illustrating a carrier according to an embodiment.

FIG. 10 is a front view illustrating a carrier, a polishing head and a polishing part according to an embodiment.

FIG. 11 is a perspective view illustrating a carrier according to an embodiment.

FIG. 12 is a front view illustrating a carrier, a polishing head and a polishing part according to an embodiment.

FIG. 13 is a perspective view illustrating a carrier according to an embodiment.

FIG. 14 is a front view illustrating a carrier, a polishing head and a polishing part according to an embodiment.

FIG. 15 is a perspective view illustrating a carrier according to an embodiment.

FIG. 16 is a front view illustrating a carrier, a polishing head and a polishing part according to an embodiment.

FIG. 17 is a flowchart illustrating a method of polishing a substrate according to an embodiment.

FIG. 18 is a perspective view illustrating the method of polishing a substrate according to the flowchart of FIG. 17.

FIG. 19 is a perspective view illustrating the method of polishing a substrate according to the flowchart of FIG. 17.

FIG. 20 is a perspective view illustrating the method of polishing a substrate according to the flowchart of FIG. 17.

FIG. 21 is a perspective view illustrating the method of polishing a substrate according to the flowchart of FIG. 17.

FIG. 22 is a plan view illustrating the method of polishing a substrate according to the flowchart of FIG. 17.

### DETAILED DESCRIPTION

Hereinafter, embodiments of the disclosure will be described in detail with reference to the accompanying drawings. The same reference numerals or the same reference labels may denote the same components or elements throughout the specification.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

Hereinafter, a reference label D1 may indicate a first direction D1, a reference label D2 intersecting the first direction D1 may indicate a second direction D2, and a reference label D3 intersecting both the first direction D1 and the second direction D2 may indicate a third direction D3. The first direction D1 may also be referred to as an upward direction, and an opposite direction to the first direction D1 may also be referred to as a downward direction. The first direction D1 may also be referred to as a vertical direction. In addition, each of the second direction D2 and the third direction D3 may also be referred to as a horizontal direction. For example, the second direction D2 may be referred to as a first horizontal direction and the third direction D3 may be referred to as a second horizontal direction. Moreover, a reference label D4 may indicate a fourth direction D4, which may have a difference of about 150° from the third direction D3. However, since the fourth direction D4 was introduced for convenience of description of the invention, it is not limited to the above description. The fourth direction D4 may be referred to as a third horizontal direction.

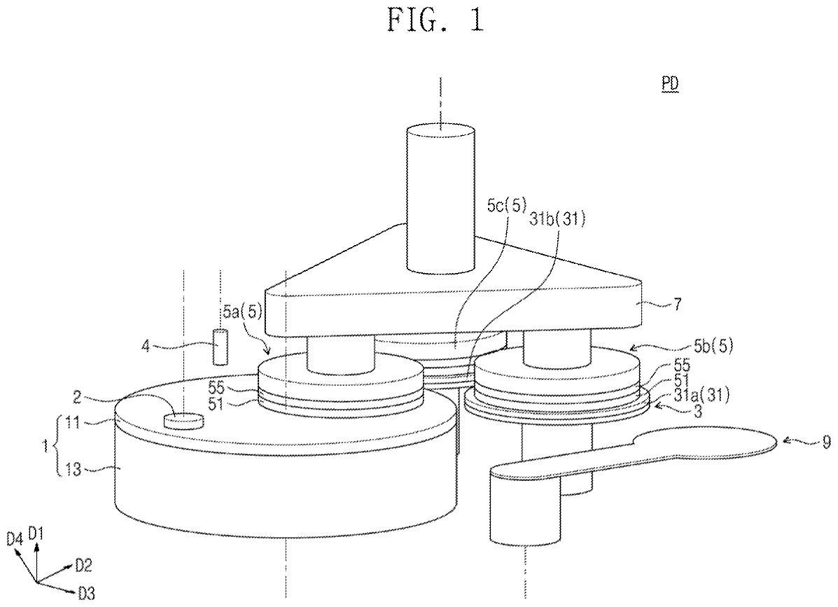

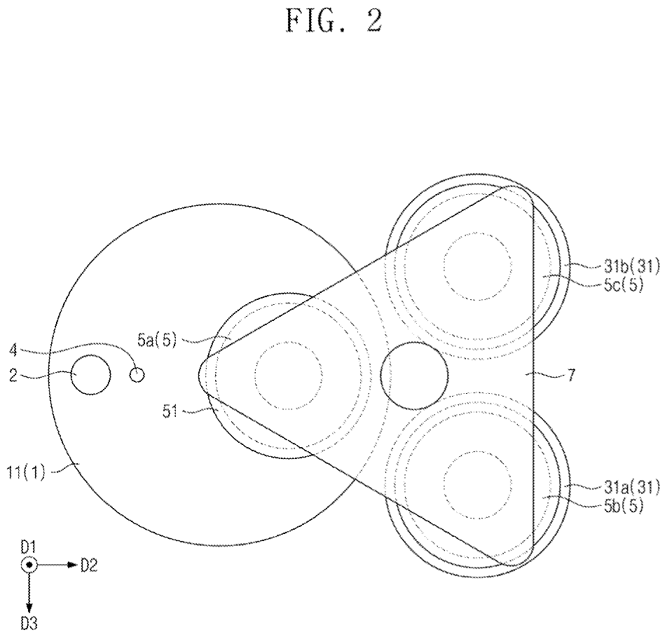

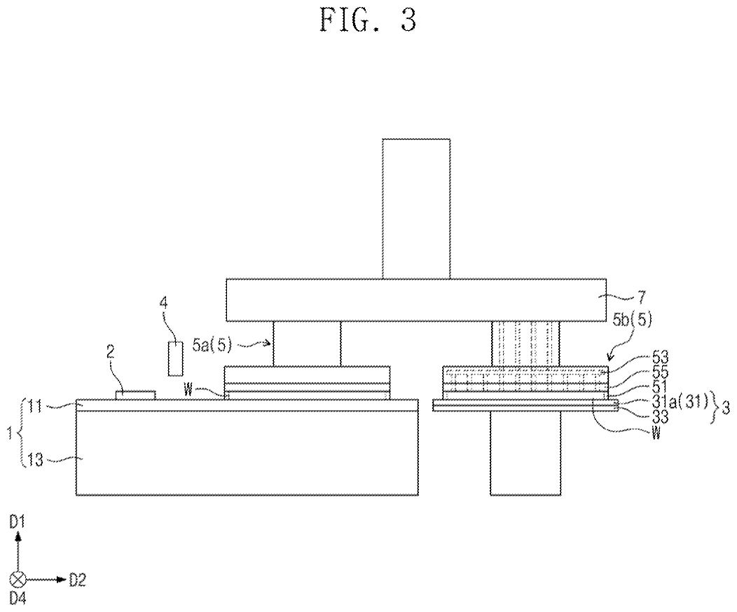

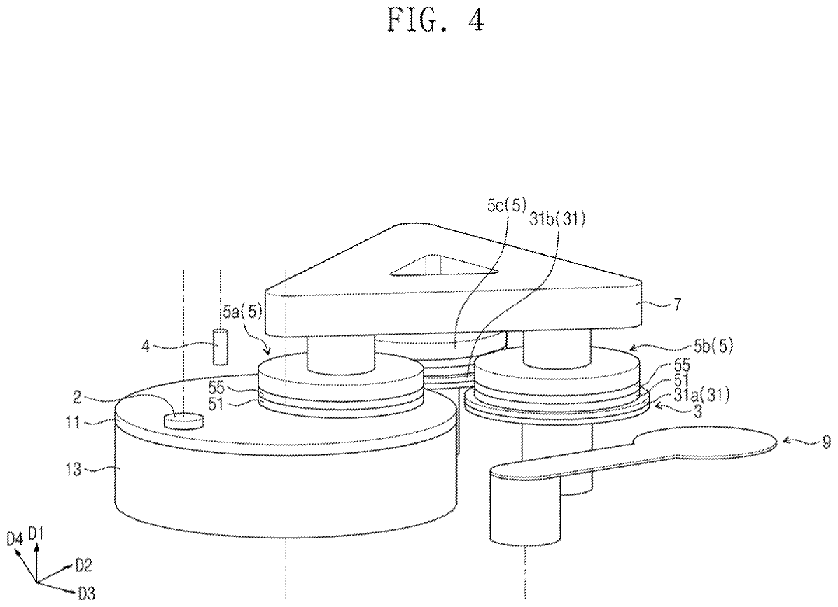

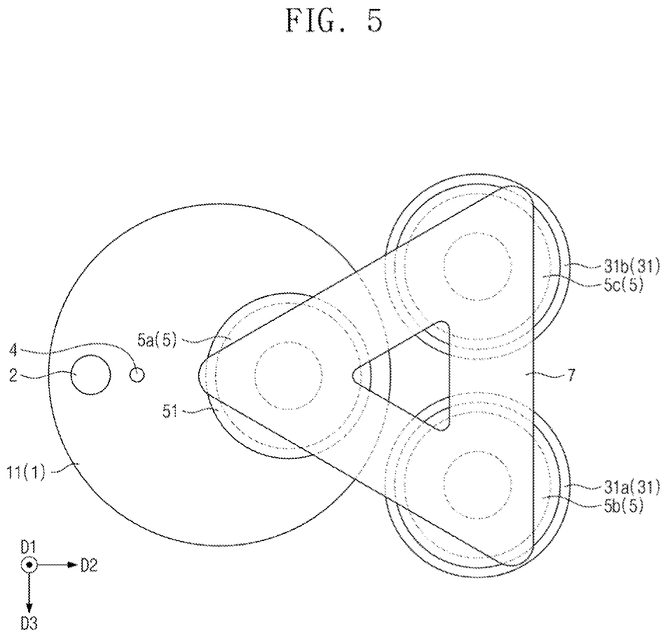

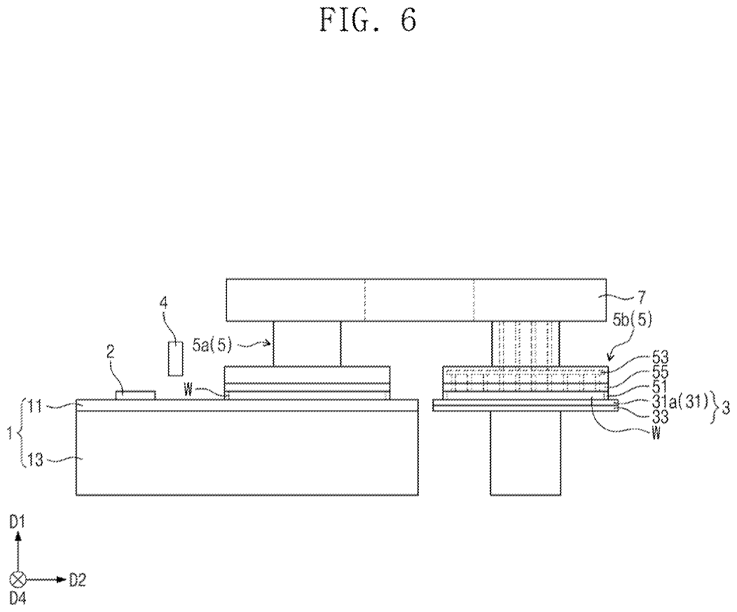

FIGS. 1 and 4 are perspective views illustrating a chemical mechanical polishing apparatus according to an embodiment, FIGS. 2 and 5 are plan views illustrating a chemical mechanical polishing apparatus according to an embodiment, and FIGS. 3 and 6 are front views illustrating a chemical mechanical polishing apparatus according to an embodiment.

Referring to FIGS. 1 to 6, a chemical mechanical polishing apparatus PD may be provided. The chemical mechanical polishing apparatus PD may be configured to perform a polishing process on a substrate W. According to an embodiment, the term ‘substrate’ may mean a silicon (Si) wafer. However, the disclosure is not limited thereto, and as such, the substrate may include other types of wafers. The chemical mechanical polishing apparatus PD may include a main polishing part 1, an auxiliary polishing part 3, a polishing head 5, a conditioning unit 2, a slurry supply unit 4, a polishing head transferring member 7, and a carrier 9. However, the disclosure is not limited thereto, and as such, according to another embodiment, one or more additional components may be included in the chemical mechanical polishing apparatus PD or one or more components may be omitted from the chemical mechanical polishing apparatus PD.

The main polishing part 1 may include a main polishing pad 11 and a main plate 13. The main polishing pad 11 may be located on the main plate 13. For example, a bottom surface of the main polishing pad 11 may be in contact with a top surface of the main plate 13. A center of rotation of the main polishing pad 11 may be located on the same line as a center of rotation of the main plate 13. The main polishing pad 11 may polish the substrate W. The main polishing part 1 may be rotatable. For example, the main polishing part 1 may rotate about a rotation axis parallel to the first direction D1. A top surface of the rotating main polishing pad 11 may come in contact with the substrate W to polish a bottom surface of the substrate W. According to an embodiment, a process of polishing the substrate W by the main polishing pad 11 may be defined as a main polishing process. A radius of the main polishing pad 11 may be greater than a radius of the substrate W. Hereinafter, the radius of the main polishing pad 11 may be referred to as a first radius. According to an embodiment, the main polishing pad 11 may be divided into a plurality of regions. However, the disclosure is not limited thereto. The first radius may be less than a radius of the main plate 13. For example, the main polishing pad 11 and the main plate 13 may be concentric in a plan view. According to an embodiment, the term of the plan view may mean a top view as illustrated in FIG. 2.

The auxiliary polishing part 3 may be spaced apart from the main polishing part 1. The auxiliary polishing part 3 may be rotatable. For example, the auxiliary polishing part 3 may be rotatable independently of the main polishing part 1. The auxiliary polishing part 3 may be rotatable about a rotation axis parallel to the first direction D1. The auxiliary polishing part 3 may include an auxiliary polishing pad 31 and an auxiliary plate 33. The auxiliary polishing pad 31 may be located on the auxiliary plate 33. For example, a bottom surface of the auxiliary polishing pad 31 may be in contact with a top surface of the auxiliary plate 33. A center of rotation of the auxiliary polishing pad 31 may be located on the same line as a center of rotation of the auxiliary plate 33. The auxiliary polishing pad 31 may be spaced apart from the main polishing pad 11 in a horizontal direction. The auxiliary polishing pad 31 may polish the substrate W. A top surface of a rotating auxiliary polishing pad 31 may come in contact with the substrate W to polish one surface of the substrate W. According to an embodiment, a process of polishing the substrate W by the auxiliary polishing pad 31 may be defined as an auxiliary polishing process. The auxiliary polishing pad 31 may include the same material as the main polishing pad 11. However, the disclosure is not limited thereto, and as such, according another embodiment, the auxiliary polishing pad 31 and the main polishing pad 11 may include different materials and/or may perform different functions in a process of polishing the substrate W. The auxiliary polishing process may be different from the main polishing process. The auxiliary polishing process may be a process for increasing uniformity of a thickness of the substrate W. The auxiliary polishing process may be a process of polishing an edge portion of the substrate W. The auxiliary polishing process may be a process of feeding the substrate W to reduce a loss of polycrystalline silicon (poly-silicon). However, the disclosure is not limited thereto, and as such, according to another embodiment, one or more other types of processes may be performed. The auxiliary polishing process may be performed before and/or after the main polishing process. Although the term “main” and “auxiliary” are used to describe various components, the disclosure is not limited thereto, and as such, “first” and “second” may be used in other embodiments. For instance, the main polishing part 1 may be referred to as a first polishing part 1 and the auxiliary polishing part 3 may be referred to as a second polishing part 3. Also, the main polishing pad 11 may be referred to as a first polishing pad 11, the main plate 13 may be referred to as a first plate 13, the auxiliary polishing pad 31 may be referred to as a first polishing pad 31, and the auxiliary plate 33 may be referred to as a first plate 33. In another embodiment, the term “main” may be replaced with “primary” and the term “auxiliary” may be replaced with “secondary”.

The auxiliary polishing part 3 may include a plurality of auxiliary polishing part 3. For example, a number of the auxiliary polishing parts 3 may be two or more. Hereinafter, a single auxiliary polishing part 3 will be described as a representative of the plurality of auxiliary polishing parts 3 for the purpose of ease and convenience in explanation. A radius of the auxiliary polishing pad 31 may be less than the first radius. Hereinafter, the radius of the auxiliary polishing pad 31 may be referred to as a second radius.

The polishing head 5 may be configured to support and/or rotate the substrate W. For example, the polishing head 5 may provide the substrate W on the main polishing pad 11 and/or the auxiliary polishing pad 31 in such a way that a first surface of the substrate W faces the main polishing pad 11 and/or the auxiliary polishing pad 31. Hereinafter, the main polishing pad 11 and/or the auxiliary polishing pad 31 may be referred to as ‘a polishing pad 11 and/or 31’. According to an embodiment, a radius of the polishing head 5 may be less than the first radius. However, the disclosure is not limited thereto, and as such, the ration of the polishing head 5 may vary. The polishing head 5 may include a plurality heads. For example, the polishing head 5 may include a first polishing head 5a, a second polishing head 5b and a third polishing head 5c. The polishing head 5a may be located on a polishing pad 11 and the polishing heads 5b and 5c may be located on polishing pads 31y. Hereinafter, a single polishing head 5 will be mainly described for the purpose of ease and convenience in explanation. The first polishing head 5a on the main polishing pad 11 may be a main polishing head 5a. The second polishing heads 5b and 5c on the auxiliary polishing pads 31 may be an auxiliary polishing head 5b or 5c. The auxiliary polishing head 5b or 5c and the main polishing head 5a may have substantially the same structure. The polishing head 5 may be rotatable independently of the main polishing part 1 and/or the auxiliary polishing part 3. Hereinafter, the main polishing part 1 and/or the auxiliary polishing part 3 may be referred to as ‘a polishing part 1 and/or 3’. The polishing head 5 may be movable in a horizontal direction on the polishing pad 11 and/or 31. The polishing head 5 may rise in the upward direction from a place where the one surface of the substrate W is in contact with the polishing pad 11 and/or 31. The polishing head 5 may include a retainer ring 51, a membrane 55, and a vacuum tube 53.

Referring to FIGS. 2, 3, 5 and 6, the retainer ring 51 may be coupled to a bottom surface of the membrane 55. For example, a top surface of the retainer ring 51 may be in contact with the bottom surface of the membrane 55. The retainer ring 51 may support the substrate W. For example, the retainer ring 51 may surround a circumference of the substrate W.

The membrane 55 and the vacuum tube 53 will be described later in detail.

Referring to FIGS. 1 to 6, the polishing head transferring member 7 may be provided. The polishing head transferring member 7 may be connected to the plurality of polishing heads 5. The polishing head transferring member 7 may include a rotary motor capable of rotating the plurality of polishing heads 5 in a clockwise direction or a counterclockwise direction. For example, the polishing head transferring member 7 may include a rotary motor capable of rotating the main polishing head 5a and the plurality of auxiliary polishing heads 5b and 5c. Referring to FIGS. 4 to 6, the polishing head transferring member 7 may include a conveyor line. However, the disclosure is not limited thereto, and as such, according to another embodiment, the polishing head transferring member 7 may include at least one of other various components. Since the polishing head transferring member 7 is operated, the polishing head transferring member 7 may locate the polishing head 5 onto a desired one of the polishing pads 11 and 31. An order of polishing processes of the substrate W coupled to the polishing head 5 may be changed by the polishing head transferring member 7.

The carrier 9 will be described later in detail.

Referring to FIGS. 1 to 6, the conditioning unit 2 may be provided. The conditioning unit 2 may be configured to polish a portion of the polishing pad 11 and/or 31. The conditioning unit 2 may selectively contact the top surface of the polishing pad 11 and/or 31. While the polishing pad 11 and/or 31 rotates, the conditioning unit 2 may come in contact with the top surface of the polishing pad 11 and/or 31. By the polishing of the conditioning unit 2, a state of the top surface of the polishing pad 11 and/or 31 may be changed in the process of polishing the substrate W. In other words, the conditioning unit 2 may polish the polishing pad 11 and/or 31 to improve the state of the polishing pad 11 and/or 31. The conditioning unit 2 may be rotatable independently of the polishing part 1 and/or 3. A rotational speed of the conditioning unit 2 relative to a rotational speed of the polishing part 1 and/or 3 may be changed according to a time. A relative position of the conditioning unit 2 on the polishing part 1 and/or 3 may be changed according to a time. The conditioning unit 2 may be movable in a horizontal direction on the polishing pad 11 and/or 31. The conditioning unit 2 may rise in the upward direction from a place where a bottom surface of the conditioning unit 2 is in contact with the polishing pad 11 and/or 31.

Referring to FIGS. 1 to 6, the slurry supply unit 4 may be provided. The slurry supply unit 4 may be configured to supply slurry to the polishing pad 11 and/or 31. For example, the slurry supply unit 4 may supply the slurry to the top surface of the polishing pad 11 and/or 31 to smoothly perform the process of polishing the substrate W. The slurry supply unit 4 may be spaced apart from the polishing pad 11 and/or 31 in a vertical direction. The slurry supply unit 4 may be located between the conditioning unit 2 and the polishing head 5.

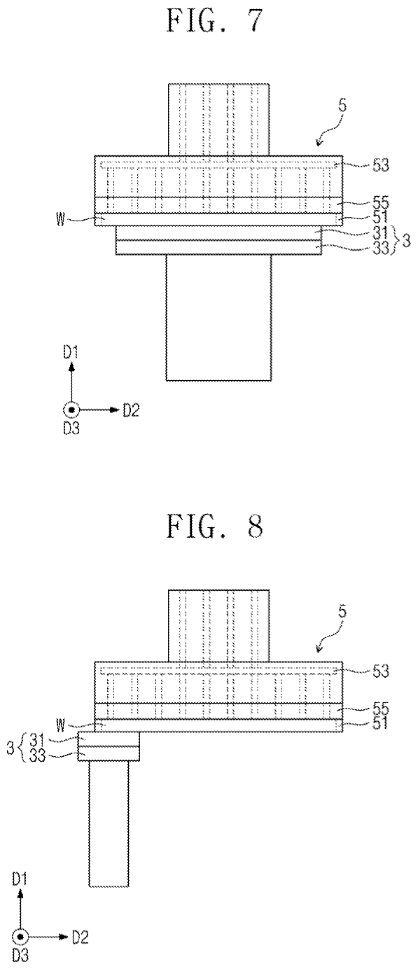

FIGS. 7 and 8 are front views illustrating the polishing head 5 and the auxiliary polishing part 3 according to an embodiment.

A size of the auxiliary polishing part 3 may be various. Referring to FIGS. 7 and 8, the radius of the polishing head 5 may be greater than the second radius. However, the disclosure is not limited thereto. According to an example embodiment, the second radius may range from about 0.6 times to about 1.4 times the radius of the polishing head 5. However, the disclosure is not limited thereto, and as such, according to another embodiment, the second radius may be equal to or less than about 0.5 times the radius of the polishing head 5. When the auxiliary polishing pad 31 performs the process of polishing the edge portion of the substrate W, the radius of the polishing head 5 may be less than a sum of the second radius and a horizontal distance between a center of the polishing head 5 and a center of the auxiliary polishing pad 31.

Referring to FIGS. 7 and 8, the polishing head 5 may include the vacuum tube 53 and the membrane 55. The vacuum tube 53 may be located in the polishing head 5. The vacuum tube 53 may be configured to apply a vacuum pressure to the substrate W. The substrate W may be fixed to the polishing head 5 by the vacuum pressure of the vacuum tube 53. For example, the substrate W may be fixed to a bottom surface of the membrane 55 by the vacuum pressure applied from the vacuum tube 53. The membrane 55 may correspond to a lower portion of the polishing head 5. The membrane 55 may have a porous structure. The vacuum tube 53 may extend into the membrane 55. The membrane 55 may have elasticity. The membrane 55 may apply a pressure to another surface of the substrate W to allow the polishing pad 11 and/or 31 to polish the one surface of the substrate W. The membrane 55 may be divided into a plurality of areas, but the disclosure is not limited thereto. According to an embodiment, at least one of the areas of the membrane 55 may be inclined by the vacuum pressure applied from the vacuum tube 53. A polishing degree and/or a polishing speed of the substrate W may be controlled by adjusting the vacuum pressure.

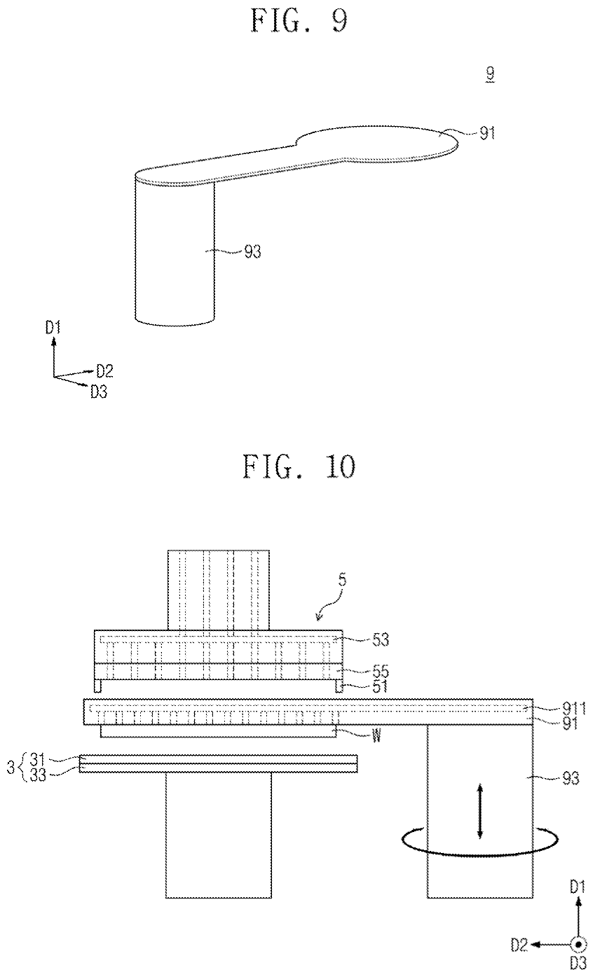

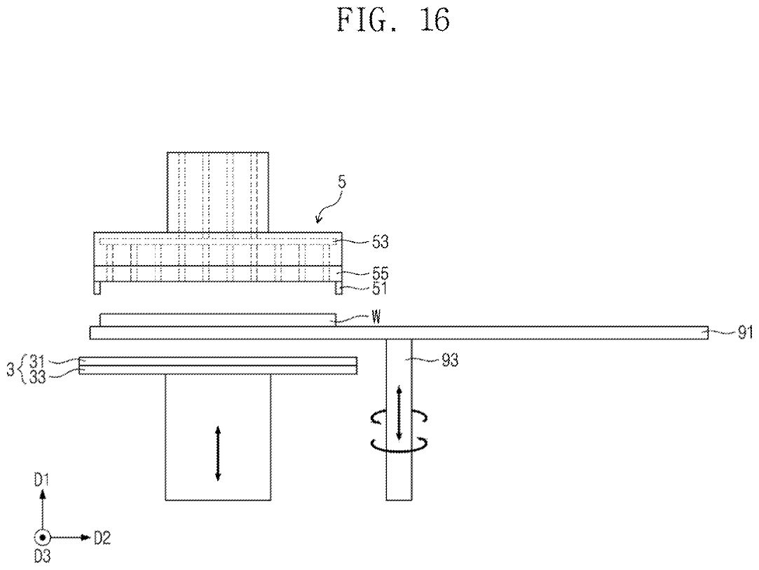

FIGS. 9, 11, 13 and 15 are perspective views illustrating carriers 9 according to an embodiment, and FIGS. 10, 12, 14 and 16 are front views illustrating carriers 9, polishing heads 5 and auxiliary polishing parts 3 according to an embodiment.

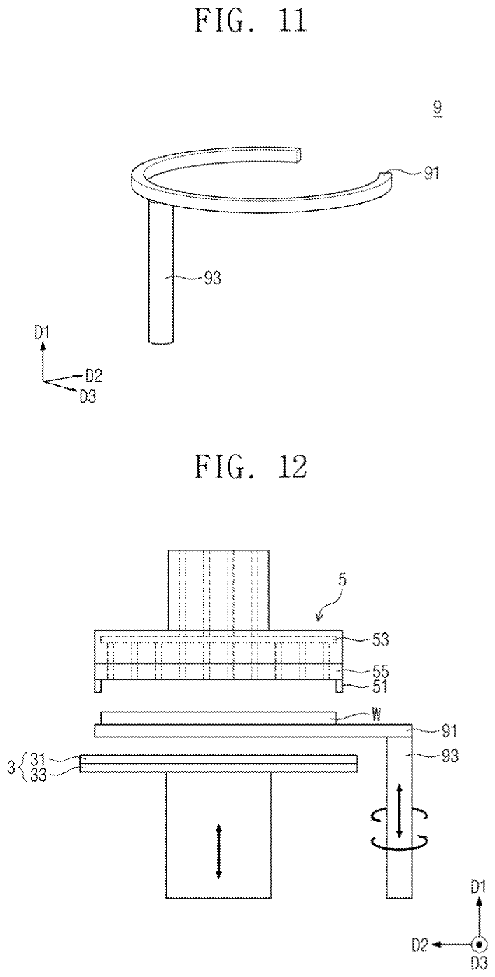

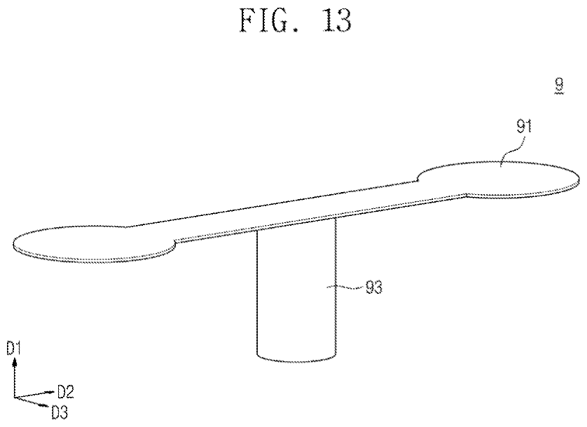

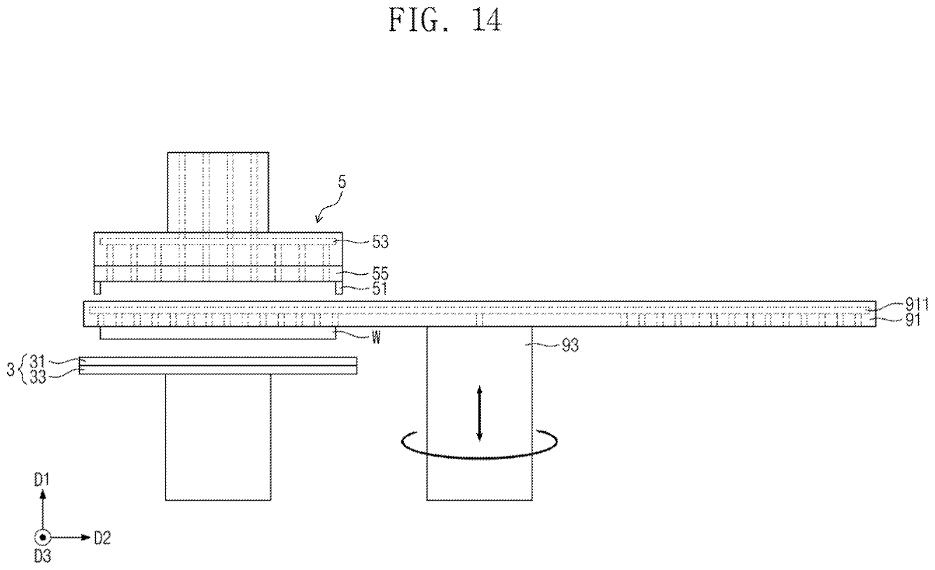

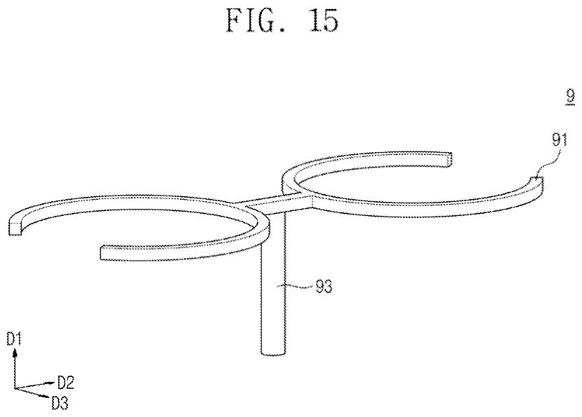

The carrier 9 may be configured to transfer the substrate W into the chemical mechanical polishing apparatus PD. The carrier 9 may be movable in a vertical direction. The carrier 9 may be rotatable. The carrier 9 may include a carrier holder 91 and a carrier rotating part 93. The carrier holder 91 may support the substrate W. Referring to FIGS. 9 and 10, the carrier holder 91 may include a vacuum tube 911 for applying a vacuum pressure to the substrate W. A top surface of the substrate W may come in contact with a bottom surface of the carrier holder 91, and the substrate W may be attached to the carrier holder 91 by the vacuum pressure. The carrier holder 91 may include a disk shape. Referring to FIGS. 11 and 12, the carrier holder 91 may have a horseshoe shape. The bottom surface of the substrate W may come in contact with a top surface of the carrier holder 91. However, a coupling method between the substrate W and the carrier holder 91 is not limited thereto, and in certain embodiments, the substrate W and the carrier holder 91 may be coupled to each other by at least one of other various methods such as electromagnetic force and a coupling member. Referring to FIGS. 13 to 16, the carrier holder 91 may include a plurality of carrier holders 91. The plurality of carrier holders 91 may be coupled to the carrier rotating part 93. In certain embodiments, the plurality of carrier holders 91 may support the substrate W by different methods. Hereinafter, a single carrier holder 91 will be mainly described for the purpose of ease and convenience in explanation.

The carrier rotating part 93 may be configured to rotate the carrier holder 91. The carrier rotating part 93 may rotate the carrier holder 91 in a clockwise direction or a counterclockwise direction. The carrier rotating part 93 may include a rotary motor. In the case in which the carrier holder 91 includes a plurality of carrier holders, the carrier rotating part 93 may rotate the plurality of carrier holders 91 at the same time.

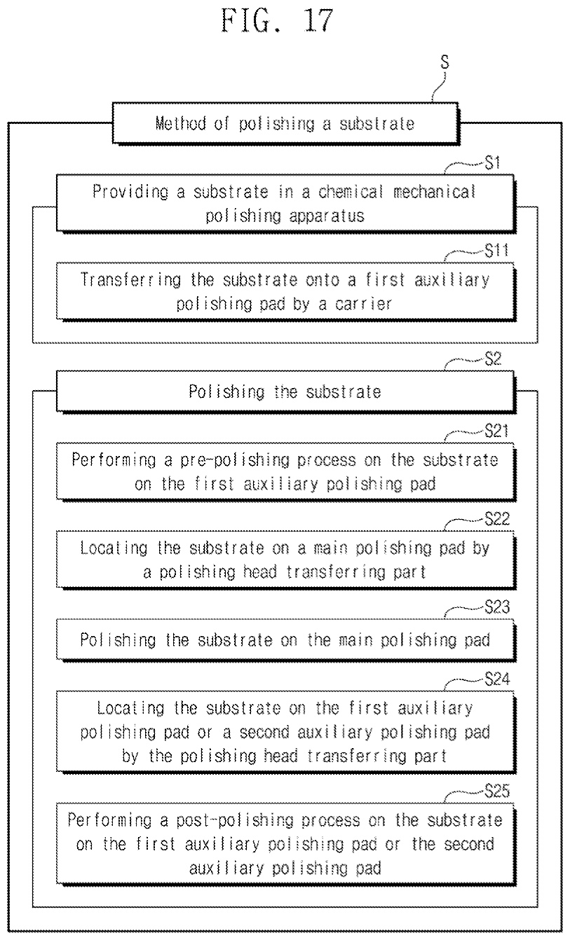

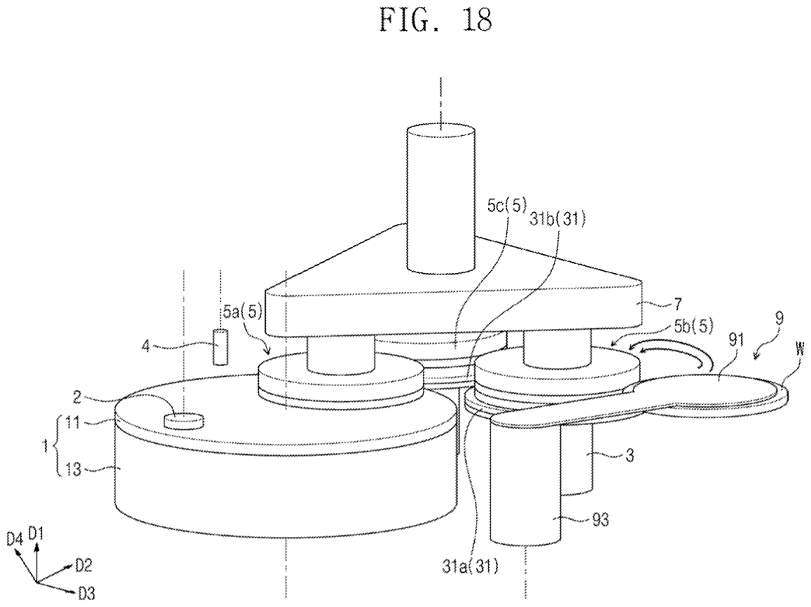

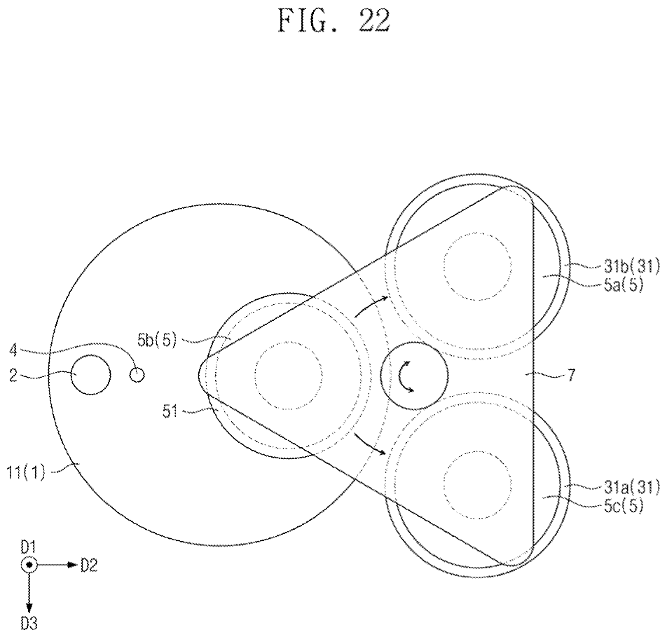

FIG. 17 is a flowchart illustrating a method of polishing a substrate (S) according to an embodiment, FIGS. 18, 19, 20 and 21 are perspective views illustrating the method of polishing a substrate (S) according to the flowchart of FIG. 17, and FIG. 22 is a plan view illustrating the method of polishing a substrate (S) according to the flowchart of FIG. 17.

Referring to FIG. 17, the method of polishing a substrate (S) may include providing a substrate W in the chemical mechanical polishing apparatus PD (S1) and polishing the substrate W (S2). According to an example embodiment illustrated in the flowchart of FIG. 17, the chemical mechanical polishing apparatus PD includes one main polishing pad 11 and two auxiliary polishing pads 31. However, the disclosure is not limited thereto, and as such, the number of the main polishing pad 11 may be different than 1 and the number of the auxiliary polishing pads 31 may be different than two. The auxiliary polishing pads 31 may include a first auxiliary polishing pad 31a and a second auxiliary polishing pad 31b. According to an embodiment, auxiliary polishing processes performed on the first auxiliary polishing pad 31a and the second auxiliary polishing pad 31b may be same or substantially the same as each other. However, the disclosure is not limited thereto, and as such, according to another embodiment, polishing processes performed on the first auxiliary polishing pad 31a and the second auxiliary polishing pad 31b may be different. That is, the first auxiliary polishing pad 31a and the second auxiliary polishing pad 31b may perform different auxiliary polishing processes. According to an embodiment, the providing of the substrate W in the chemical mechanical polishing apparatus PD (S1) may include transferring the substrate W onto the first auxiliary polishing pad 31a by the carrier 9 (S11). According to an embodiment, the polishing of the substrate W (S2) may include performing a pre-polishing process (e.g., an auxiliary polishing process) on the substrate W on the first auxiliary polishing pad 31a (S21), locating the substrate W on the main polishing pad 11 by the polishing head transferring member 7 (S22), polishing the substrate W on the main polishing pad 11 (S23), locating the substrate W on the first auxiliary polishing pad 31a or the second auxiliary polishing pad 31b by the polishing head transferring member 7 (S24), and performing a post-polishing process on the substrate W on the first auxiliary polishing pad 31a or the second auxiliary polishing pad 31b (S25). According to an embodiment, locating the substrate W on the main polishing pad 11 may include transferring the substrate W from the first auxiliary polishing pad 31a and placing the substrate W on the main polishing pad 11 by the polishing head transferring member 7. Moreover, locating the substrate W on the first auxiliary polishing pad 31a or the second auxiliary polishing pad 31b may include transferring the substrate W from the main polishing pad 11 and placing the substrate W on the first auxiliary polishing pad 31a or the second auxiliary polishing pad 31b by the polishing head transferring member 7.

Referring to FIGS. 10, 12, 14, 16 and 18, the substrate W may be located on the first auxiliary polishing pad 31a by the carrier 9. The polishing head 5 may move in the vertical direction. The carrier 9 may move in the vertical direction (e.g., direction D1). The carrier 9 may be rotated. For example, the carrier holder 91 may be rotated by the carrier rotating part 93. The carrier 9 may fix the substrate W to the carrier holder 91 by using the vacuum pressure. However, the disclosure is not limited thereto, and as such, the carrier 9 may fix the substrate W to the carrier holder 91 in a different manner. The carrier holder 91 may be rotated by the carrier rotating part 93. The carrier 9 may locate the substrate W on the first auxiliary polishing pad 31a. The polishing head 5 may be spaced apart from the first auxiliary polishing pad 31a in the vertical direction. In other words, the carrier 9 may locate the substrate W under the polishing head 5 raised in the vertical direction. Referring to FIGS. 12 and 16, when the substrate W is located on the top surface of the carrier holder 91, the polishing head 5 may move downward to bring the top surface of the substrate W into contact with the bottom surface of the polishing head 5. The carrier holder 91 may bring the substrate W into contact with the first auxiliary polishing pad 31a or the polishing head 5, and then, the carrier holder 91 may move away from a vertical line of the first auxiliary polishing pad 31a and the polishing head 5. When the substrate W is in contact with the bottom surface of the polishing head 5, the substrate W may be supported by the retainer ring 51 in contact with the bottom surface of the polishing head 5.

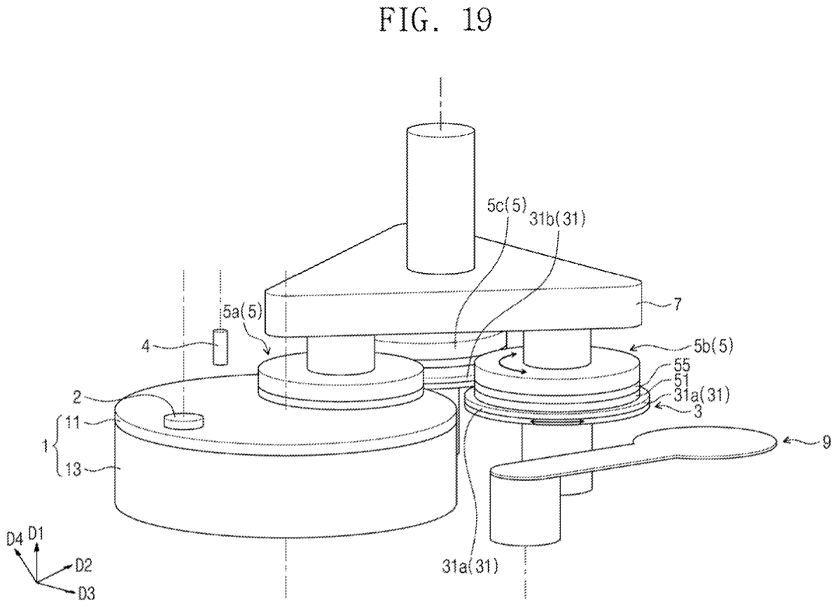

Referring to FIG. 19, a first auxiliary polishing process may be performed on the substrate W by the first auxiliary polishing pad 31a. According to an embodiment, the first auxiliary polishing process may be a process different from the main polishing process, but the disclosure not limited thereto. The radius of the first auxiliary polishing pad 31a may be changed depending on a kind and a purpose of the process. For example, when the polishing process is performed on an edge or a local portion of the substrate W, the radius of the first auxiliary polishing pad 31a may be less than the radius of the substrate W. When the polishing process is performed on the whole of the substrate W, the radius of the first auxiliary polishing pad 31a may be greater than the radius of the substrate W. When the first auxiliary polishing process is performed, the polishing head 5 may be rotated.

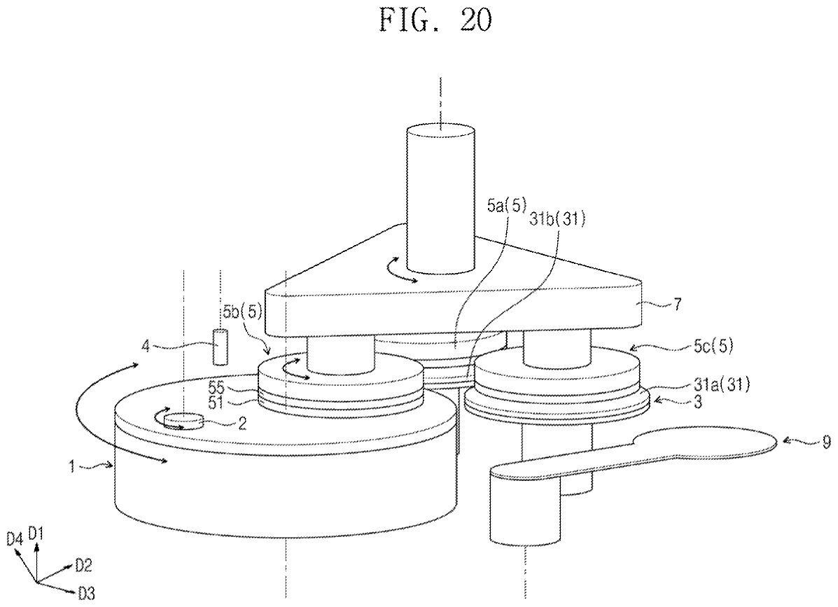

Referring to FIG. 20, the polishing head 5 on the first auxiliary polishing pad 31a may be moved onto the main polishing pad 11 by the polishing head transferring member 7. The polishing head 5 may be moved from one of the polishing pads 11 and/or 31 onto another of the polishing pads 11 and/or 31 by the polishing head transferring member 7. The polishing head transferring member 7 may move the polishing head 5 by using the rotary motor or the conveyor line. However, the disclosure is not limited thereto. The main polishing process may be performed on the substrate moved on the main polishing pad 11. When the main polishing process is performed, the main polishing pad 11 may be rotated. The conditioning unit 2 may be rotated independently of the main polishing pad 11. The conditioning unit 2 may polish the main polishing pad 11. The slurry may be supplied from the slurry supply unit 4 onto the main polishing pad 11.

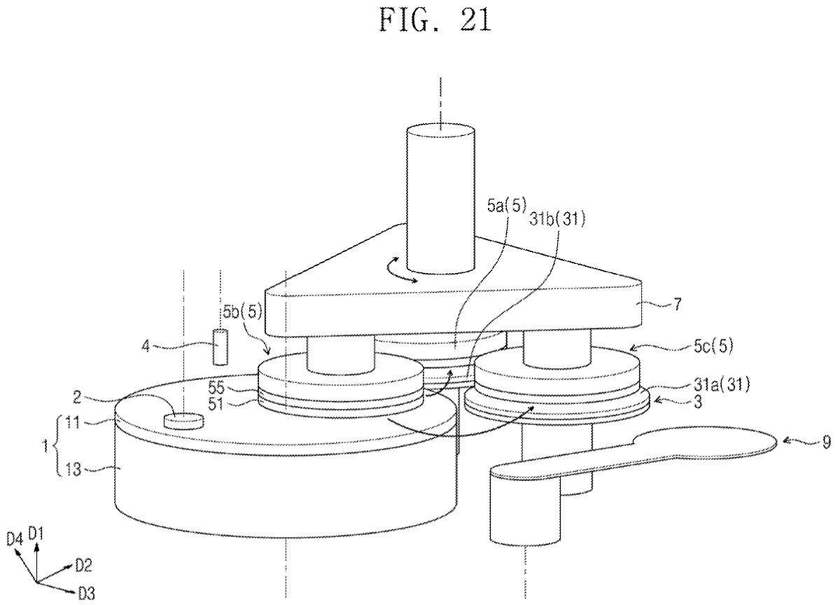

Referring to FIGS. 21 and 22, after the main polishing process is finished, the substrate W may be moved onto the first auxiliary polishing pad 31a or the second auxiliary polishing pad 31b. For example, the polishing head 5 supporting the substrate W may be moved onto the first auxiliary polishing pad 31a or the second auxiliary polishing pad 31b by the polishing head transferring member 7. The first auxiliary polishing process may be performed on the substrate W on the first auxiliary polishing pad 31a again. A second auxiliary polishing process may be performed on the substrate W on the second auxiliary polishing pad 31b. The second auxiliary polishing process may be the same as the first auxiliary polishing process. However, the disclosure is not limited thereto, and as such, according to another embodiment, the second auxiliary polishing process may be different from the first auxiliary polishing process. In an example embodiment, a process different from the first auxiliary polishing process may be performed on the substrate W by the first auxiliary polishing pad 31a.

According to the chemical mechanical polishing apparatus and the method of polishing a substrate, the auxiliary polishing process as well as the main polishing process may be performed in a single chemical mechanical polishing apparatus according to an embodiment.

According to the chemical mechanical polishing apparatus and the method of polishing a substrate, the auxiliary polishing process may be performed on a local portion of the substrate according to an embodiment.

According to the chemical mechanical polishing apparatus and the method of polishing a substrate, the plurality of polishing heads may be moved together to perform the main or auxiliary polishing process according to an embodiment.

According to the chemical mechanical polishing apparatus and the method of polishing a substrate, the chemical mechanical polishing apparatus may include the carrier capable of transferring the substrate from the outside into the chemical mechanical polishing apparatus according to an embodiment.

While the embodiments of the disclosure have been particularly shown and described, it will be understood by one of ordinary skill in the art that variations in form and detail may be made therein without departing from the spirit and scope of the attached claims.

What is claimed is:

1. A chemical mechanical polishing apparatus comprising:
a first polishing pad configured to polish a substrate;
a first polishing head on the first polishing pad and configured to support the substrate; and
a second polishing pad spaced apart from the first polishing pad in a horizontal direction,
wherein a radius of the second polishing pad is less than a radius of the first polishing pad.

2. The chemical mechanical polishing apparatus of claim 1, wherein a radius of the first polishing head is less than the radius of the first polishing pad.

3. The chemical mechanical polishing apparatus of claim 1, wherein the radius of the second polishing pad ranges from about 0.6 times to about 1.4 times a radius of the first polishing head.

4. The chemical mechanical polishing apparatus of claim 1, wherein the radius of the second polishing pad is equal to or less than about 0.5 times a radius of the first polishing head, and
wherein the radius of the first polishing head is less than a sum of the radius of the second polishing pad and a horizontal distance between a center of the first polishing head and a center of the second polishing pad.

5. The chemical mechanical polishing apparatus of claim 1, further comprising:
a second polishing head located on the second polishing pad; and
a polishing head transferring member connected to the first polishing head and the second polishing head.

6. The chemical mechanical polishing apparatus of claim 5, wherein the polishing head transferring member comprises: a rotary motor configured to rotate the first polishing head and the second polishing head in a clockwise direction or a counterclockwise direction.

7. The chemical mechanical polishing apparatus of claim 1, wherein the first polishing head comprises: a vacuum tube configured to apply a vacuum pressure to the substrate.

8. The chemical mechanical polishing apparatus of claim 1, further comprising:
a retainer ring in contact with a bottom surface of the first polishing head, the retainer ring configured to support the substrate.

9. The chemical mechanical polishing apparatus of claim 1, further comprising:
a conditioner configured to polish the first polishing pad; and
a slurry supplier configured to supply slurry onto the first polishing pad.

10. The chemical mechanical polishing apparatus of claim 1, further comprising:
a carrier configured to transfer the substrate into the chemical mechanical polishing apparatus,
wherein the carrier comprises:
a carrier holder configured to support the substrate; and
a carrier rotating member configured to rotate the carrier holder.

11. The chemical mechanical polishing apparatus of claim 10, wherein the carrier holder comprises: a vacuum tube configured to apply a vacuum pressure to the substrate.

12. The chemical mechanical polishing apparatus of claim 10, wherein the carrier holder includes two or more carrier holders.

13. A chemical mechanical polishing apparatus comprising:
a first polishing pad configured to polish a substrate;
a first polishing head provided on the first polishing pad;
a second polishing pad spaced apart from the first polishing pad;
a second polishing head provided on the second polishing pad;
a polishing head transferring member connected to the first polishing head and the second polishing head; and
a carrier configured to transfer the substrate onto the first polishing head or the second polishing head.

14. The chemical mechanical polishing apparatus of claim 13, wherein the polishing head transferring member comprises: a rotary motor to rotate about a central axis of the polishing head transferring member.

15. The chemical mechanical polishing apparatus of claim 13, wherein the polishing head transferring member comprises a conveyor line.

16. The chemical mechanical polishing apparatus of claim 13, wherein a radius of the second polishing pad is less than a radius of the first polishing pad.

17. The chemical mechanical polishing apparatus of claim 13, wherein the carrier comprises: a vacuum tube configured to apply a vacuum pressure to the substrate.

18. A method of polishing a substrate in a chemical mechanical polishing apparatus including a first polishing pad and a second polishing pad, the method comprising:
performing a first polishing process on a substrate on the second polishing pad;
moving the substrate to the first polishing pad; and
performing a second polishing process on the substrate on the first polishing pad.

19. The method of claim 18, wherein a radius of the first polishing pad is greater than a radius of the second polishing pad.

20. The method of claim 18, wherein the chemical mechanical polishing apparatus further includes a first polishing head located on the first polishing pad, and
wherein a radius of the first polishing head is less than a radius of the first polishing pad.
